(19) United States
(12) Patent Application Publication
(10) Pub. No.: US 2022/0052323 A1
(43) Pub. Date: Feb. 17, 2022

(54) SYNTHESIS OF GRAPHITIC SHELLS ON SILICON NANOPARTICLES

(71) Applicant: The Regents of the University of California, Oakland, CA (US)

(72) Inventors: Lorenzo Mangolini, Yorba Linda, CA (US); Giorgio Nava, Riverside, CA (US); Joseph Schwan, Riverside, CA (US)

(21) Appl. No.: 17/434,164

(22) PCT Filed: Feb. 26, 2020
(86) PCT No.: PCT/US20/19929

§ 371 Date: Aug. 26, 2021

Related U.S. Application Data
(60) Provisional application No. 62/811,388, filed on Feb. 27, 2019.

(51) Int. Cl. H01M 4/36; H01M 4/38; H01M 4/62; C23C 16/26; C23C 16/44; C23C 16/56; C01B 33/02

(52) U.S. Cl. CPC H01M 4/366; H01M 4/386; H01M 4/625; H01M 2004/027; C23C 16/4417; C23C 16/56; C01B 33/02; C23C 16/26

(57) ABSTRACT

Discussed herein are methods for making an anode material comprising silicon nanoparticles and a graphite carbon coating thereon. The method can include providing silicon nanoparticles, applying an amorphous carbon coating thereon to create an amorphous carbon shell on the silicon nanoparticles at a first temperature, and converting the amorphous carbon shell to a graphite carbon shell at a second temperature higher than the first temperature. The method can optionally include producing silicon nanoparticles by providing an argon-silane mixture, exposing the argon-silane mixture to a non-thermal plasma to convert the silane mixture to amorphous clusters, and passing the amorphous clusters through a furnace at a first temperature so as to agglomerate them to silicon nanoparticles.

### CROSS REFERENCE TO RELATED APPLICATIONS

This application claims the benefit of priority to U.S. Patent Provisional Application No. 62/811,388, filed Feb. 27, 2019, which is incorporated by reference herein in its entirety.

### STATEMENT OF GOVERNMENT INTEREST

This invention was made with U.S. Government support under CMMI-1351386 awarded by the National Science Foundation. The U.S. Government has certain rights in the invention.

### TECHNICAL FIELD

This invention relates to battery cell devices and methods. In one example, this invention relates to lithium ion batteries.

### BACKGROUND

Improved batteries, such as lithium ion batteries are desired. New materials and microstructures are desired to increase capacity, and to mitigate issues with volumetric expansion and contractions in electrode materials.

### BRIEF DESCRIPTION OF THE DRAWINGS

FIG. 1A illustrates a schematic diagram of a Chemical Vapor Deposition (CVD) reactor used to make a carbon-silicon nanocomposite anode material.

FIG. 1B illustrates a schematic diagram of a method of making carbon-silicon nanocomposite anode materials.

FIGS. 2A-2B illustrate TEM images of silicon nanoparticles (SNP) coated with amorphous (AC-SNP) and graphitic (GC-SNP) carbon shells respectively.

FIGS. 3A-3B illustrate Raman spectra of silicon nanoparticles coated with amorphous and graphitic carbon shells, respectively.

FIGS. 4A-4B illustrate bar graphs of the Energy Dispersive X-Ray Spectroscopy (EDS) chemical composition and Brunauer-Emmett-Teller (BET) specific surface area of silicon nanoparticles (SNP) coated with amorphous (AC-SNP) and graphitic (GC-SNP) carbon shells, respectively.

FIGS. 5A-5B illustrate line graphs of charge/discharge capacities of carbon coated silicon nanoparticles, and coulombic efficiency (CE) of silicon nanoparticles coated with amorphous (AC-SNP) and graphitic (GC-SNP) carbon shells, respectively.

FIG. 6 illustrates a schematic diagram depicting a method of producing silicon nanoparticles.

FIG. 7 illustrates a graph showing the size distribution of silicon nanoparticles.

FIG. 8 illustrates a schematic drawing of a battery.

### DETAILED DESCRIPTION

In the following detailed description, reference is made to the accompanying drawings which form a part hereof, and in which is shown, by way of illustration, specific embodiments in which the invention may be practiced. In the drawings, like numerals describe substantially similar components throughout the several views. These embodiments are described in sufficient detail to enable those skilled in the art to practice the invention. Other embodiments may be utilized and structural, or logical changes, etc. may be made without departing from the scope of the present invention.

### I. Silicon-Carbon Core-Shell Nanocomposites

Disclosed herein is a method of making silicon-carbon core-shell nanocomposites. The process allows application of a conformal shell of carbon with controlled thickness and degree of graphitization onto the surface of silicon nanoparticles. The nanocomposite material has a high storage capacity compared to conventional graphite-based lithium-ion battery anodes.

The process can include two steps: first, a carbonaceous precursor, such as acetylene, is dissociated at a low temperature, creating an amorphous carbon over-coating on the silicon nanoparticles in a chemical vapor deposition (CVD) step; second, excess precursor is removed from the reactor and substituted with an inert gas, such as argon, while the temperature is increased. This induces graphization of the carbon shell. Thus, the silicon nanoparticles are coated with a graphite carbon shell. The thickness of the coating can be tailored by changing the duration of the first step.

Silicon-carbon core-shell nanocomposites, including silicon nanoparticles coated with a carbon shell, may be a promising high-storage-capacity alternative to graphite-based lithium-ion battery anodes. The small size of the silicon nanostructures can tackle the large volume expansion undergone by the semiconductor upon lithiation, which can cause pulverization of bulk silicon electrodes. The carbonaceous coating can prevent the direct interaction of silicon with the electrolyte, and improve the electrical conductivity of the composite, promoting more robust and stable cycling. However, there is a lack of a facile and scalable process for the manufacture of silicon-carbon core-shell nanocomposites.

Disclosed herein is a carbon coated silicon nanocomposite, and associated methods. The method can include a two-step thermal process. A chemical precursor of carbon, such as acetylene (C₂H₂) can be dissociated at low temperature creating an amorphous carbon over-coating onto silicon nanoparticles. The chemical precursor can be a gaseous precursor, such as Acetylene or Methane, a liquid precursor, such as Benzene or Toluene, or a solid mixed with the silicon particles such as polyvinylpyrrolidone or a sugar. Next, the unreacted carbon precursor can be removed from the reaction zone, and substituted with an inert gas, such as Argon, Nitrogen, Helium, or another noble gas, and the temperature can be increased, inducing, the graphitization of the carbon shell on the silicon nanoparticles. Using this approach, silicon nanoparticles can be reproducibly coated with a graphitic carbon shell of tunable thickness.

Disclosed herein is a process for coating silicon nanoparticles with a conformal shell of carbon of controlled thickness and degree of graphitization. These types of carbon coatings can be advantageous in silicon-based battery technology. For example, bare silicon particles exhibit poor chemical stability with the most common electrolyte formulations causing the formation of an unstable solid electrolyte interphase, leading to a fast capacity fade and poor cycling stability of the electrodes. The introduction of a highly graphitic carbon coating on the surface of the silicon particles can buffer the interaction of the semiconductor with the electrolyte, promoting a more robust cycling, and improves the overall electrical conductivity of the silicon-carbon composite.

The process for the tailored coating of silicon particles with a graphitic carbon shell disclosed herein can be specifically optimized for electrochemical energy storage applications. This approach has several advantages. First, the disclosed methods can be compatible with the use of readily available commercial silicon nanoparticles and suitable for a facile scaleup.

Second, the discussed methods herein avoid pitfalls of conventional carbon coating methods of silicon. For example, carbon shells can be grown on silicon particles by employing a high temperature CVD process with a methane precursor (CH₄) and a mild oxidant, such as CO₂. Such process has the disadvantage of inducing a partial oxidation of the silicon nanoparticles, which is detrimental for their application as active materials in lithium ion battery anodes. For the proposed process, no oxidant agent is required during the carbon over-layer graphitization process.

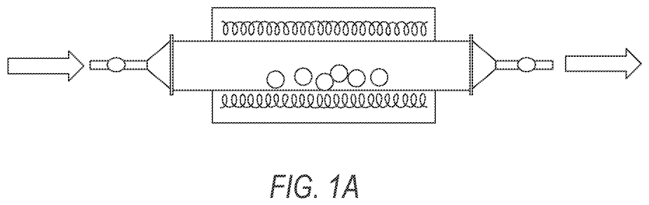

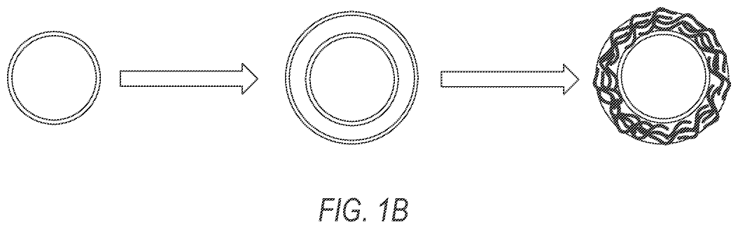

FIGS. 1A-1B display schematics of a CVD reactor setup and process of coating silicon nanoparticles. Silicon nanoparticles can be introduced into a CVD furnace. After pumping down the system to a low pressure, such as about 1 Pa, the chemical precursor of carbon can be flown inside of the furnace and the pressure can be regulated with a needle valve (situated upstream from the pumping system). Alternatively, the silicon nanoparticles can be mixed with a solid carbon precursor prior to introduction into the CVD furnace. The precursor can be thermally decomposed onto the silicon particles by increasing the temperature to reach the thermal cracking temperature of the carbon precursor, such as about 400 to about 700 and holding it constant for the desired time.

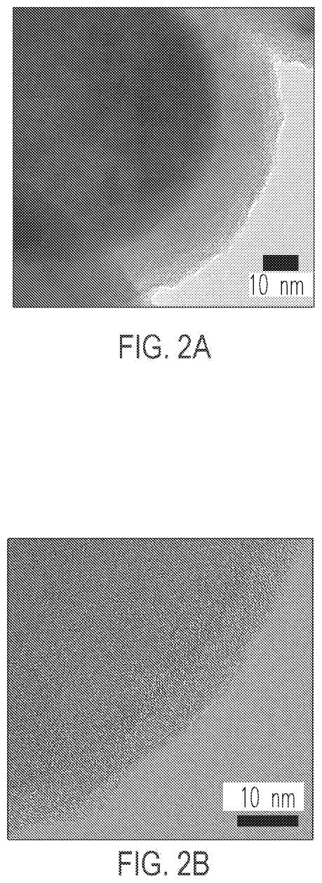

The described process can create a conformal amorphous carbon shell onto the silicon nanoparticles, as depicted in FIG. 2A. The coating thickness can be adjusted by changing the reaction time. After this first thermal step, the unreacted carbon precursor can be removed from the furnace and an inert gas can be flown into the quartz tube. The temperature can be increased to above about 700° C. and held constant: This second thermal step can induce the controlled graphitization of the conformal carbon coating, as depicted in FIG. 2B (well-visible graphitic fringes appears in the corresponding TEM micrographs).

FIGS. 2A-2B illustrate TEM images of amorphous-carbon-coated silicon nanoparticles fabricated with a C₂H₂CVD (650° C. for 30 minutes) (FIG. 2A) and graphitic-carbon-coated silicon nanoparticles fabricated with C₂H₂ CVD (650° C. for 30 minutes) followed by a high-temperature annealing in Argon (1000° C. for 10 minutes) (FIG. 2B). Well-defined graphitic fringes can be observed in FIG. 2B,

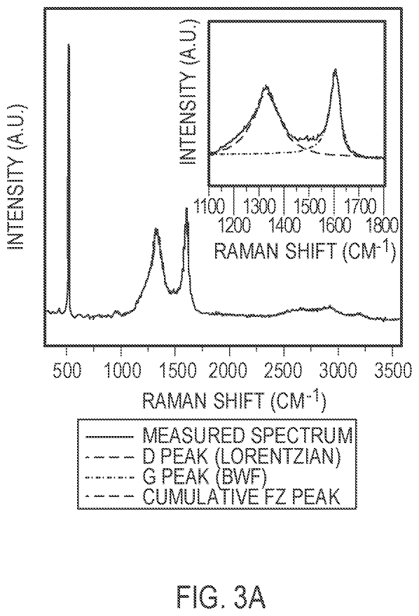

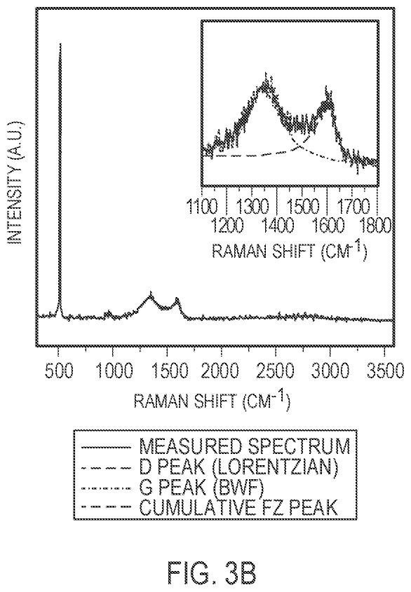

Produced materials were investigated through Raman spectroscopy to better elucidate the effect of the second high-temperature thermal step on the carbon layer properties (see FIGS. 3A-3B). The D and G mode of the carbon were fitted with a Lorentz peak and BWF peak respectively and their height ratio—I_{D}/I_{G}—, which correlates the graphitization degree of the carbonaceous material, was calculated.

FIGS. 3A-3B show Raman spectra of amorphous-carbon-coated silicon nanoparticles fabricated with a C₂H₂ CVD (650° C. for 30 minutes) (FIG. 3A) and graphitic-carbon-coated silicon nanoparticles fabricated with C₂H₂ CVD (650° C. for 30 minutes) followed by a high-temperature annealing in Argon (1000° C. for 10 minutes) (FIG. 3B). The insets display the fitting of the carbon D and G peaks which was employed to calculate the I_{D}/I_{G} ratio.

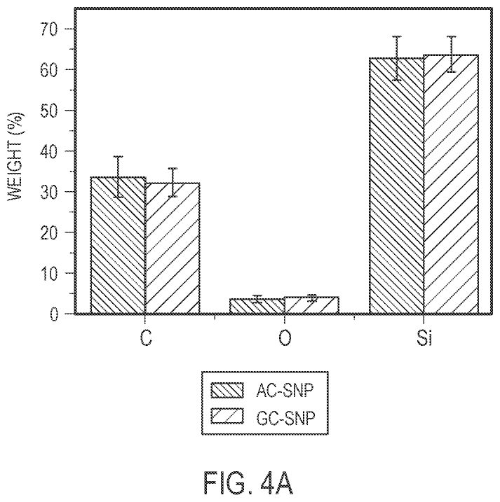

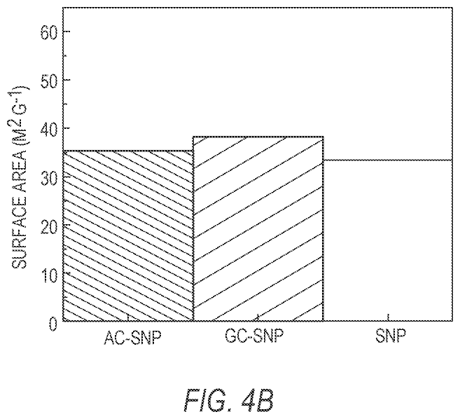

FIGS. 4A-4B show WIG ratio of the synthesized silicon-carbon composite powders as derived from Raman analysis (Table 1). Elemental composition of the synthesized silicon-carbon composite powders as derived from EDS analysis (FIG. 4B).

The carbonaceous layer produced from the C₂H₂ CVD displayed an I_{D}/I_{G} value of 0.7, compatible with a purely amorphous carbon, while, after the high temperature thermal step in Ar, the value increases to 1.2 due to the formation of graphitic carbon:

TABLE 1

| CVD Conditions | I_{D}/I_{G} |
|---|---|
| C₂H₂ (30′ @ 650° C.) | 0.7 |
| C₂H₂ (30′ @ 650° C.) + | 1.2 |
| Ar (10′ @ 1000° C.) | |

The high temperature annealing does not significantly change the chemical composition of the synthesized silicon carbon composites, nor does it change the specific surface area of the nanoparticles (see FIGS. 4A-4B).

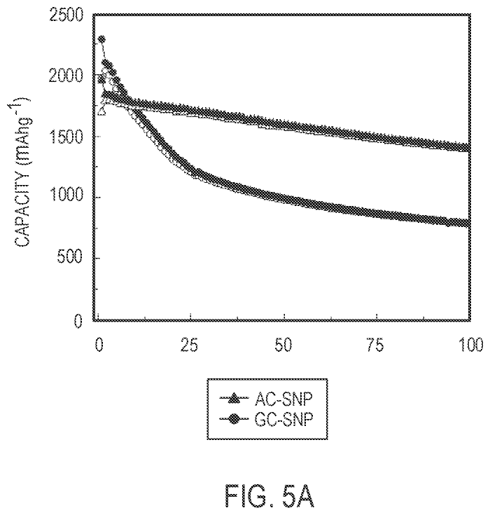

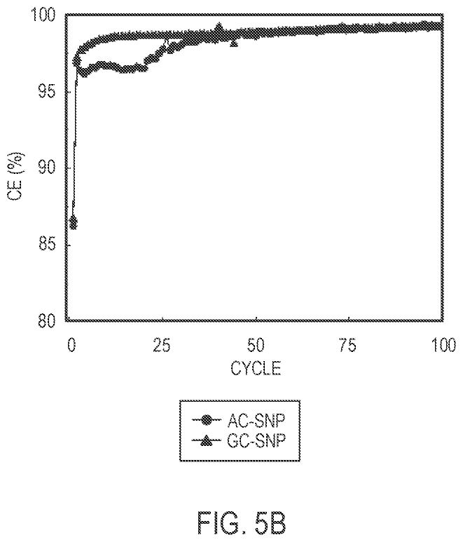

This approach has great reproducibility for coating silicon powder with conformal carbon coatings of amorphous and graphitic carbon. The amount of silicon powder that is routinely used is 300 mg that leads to a production rate of silicon-carbon composite powder of roughly 0.5 gram per batch. The as-produced silicon-carbon composites were introduced in a slurry (CMC 1% in water:silicon-carbon powder; weight ration 15:85), coated onto a copper substrate and tested as anode material in prototype Li-ion battery half-cell assemblies. Notably, no conductive additive was added to the slurry. The results are summarized in FIGS. 5A-5B. The amorphous-carbon-coated silicon particles, fabricated by applying the C₂H₂ CVD treatment at 650° C. for 30 minutes, show a first cycle coulombic efficiency (“CE”) of about 86%, capacity of 2000 mA h g⁻¹ and a pronounced capacity fading. The graphitic-carbon-coated silicon particles, fabricated by applying the C₂H₂ CVD treatment at 650° C. for 30 minutes and a second thermal step in Argon at 1000° C. for 10 minutes, displayed a strong enhancement of the electrode performance. The first cycle CE and capacity had values of 87% and 2200 mA h g⁻¹ respectively, while the capacity fading is significantly reduced with respect to the amorphous-carbon-coated particles.

FIGS. 5A-5B depict the charge/discharge capacity and Coulombic Efficiency (“CE”) of silicon nanoparticles coated with an amorphous carbon shell (C₂H₂ CVD at 650° C. for 30 minutes) and a graphitic carbon shell (CH CVD at 650° C. for 30 minutes followed by annealing in Argon at 1000° C. for 10 minutes).

II. Synthesis of Silicon Nanoparticles with Optimized Size.

Discussed here is a process for the production of silicon nanoparticles with size tunable between 1 nm and 1000 nm. This size range is of great interest for silicon-based battery technology. In this application space, particles that are too large undergo fragmentation and pulverization during battery operation. Particles that are too small can show poor performance due to the high surface area of the material and to the difficulties in controlling interfacial reactions. Particles in the intermediate size range (few hundreds of nanometers) can be produced in a short reaction time and with high precursor utilization using the processes disclosed here. Discussed herein is a process for the production of silicon particles with a size that is optimized for electrochemical energy storage applications.

Discussed herein is a two-step process in which a non-thermal plasma is used first to consume a chemical precursor and convert it into very small particles (“proto-particles”), which are then carried through an intense heat source, such as a tube furnace, to grow their size. The particle growth mechanism in the second thermal step proceeds with agglomeration and coagulation of the particles. Using this approach, silicon nanoparticles larger than 20 nm can be reproducibly obtained with very high precursor utilization rate (due to the high reactivity of the first, non-thermal plasma step) and with low diffusional losses to the wall. This can occur because the nanoparticles that enter the second thermal step have much lower diffusion coefficient (therefore probability of being lost to the wall) that an unreacted precursor still in a molecular state.

This method can be used for the production of silicon nanoparticles with size tunable between 1 nm and 1000 nm. This size range is of great interest for silicon-based battery technology. For example, particles that are too large can undergo fragmentation and pulverization during battery operation. In contrast, particles that are too small can show poor performance due to the high surface area of the material and to the difficulties in controlling interfacial reactions. Particles in the intermediate size range (about few hundreds of nanometers) can be produced in a short reaction time and with high precursor utilization using the processes disclosed here.

Gas-phase synthesis of nanoparticles can be a convenient approach for the scalable production of nanomaterials with, in principle, controllable size, structure, composition etc. Conventionally, there are two approaches to such processes. Thermal processes can use a heat source (a furnace or a thermal plasma such as a torch) to dissociate a precursor and nucleate particles. Non-thermal processes (such as a non-thermal plasma) can use high-energy electrons to create reactive species (e.g., radicals) that polymerize and eventually form nanoparticles. The first approach can generate large, agglomerated particles at high rate, but can suffer from significant diffusional losses to the wall that reduce the precursor utilization rate. The second approach can consume the precursor very fast and achieve near unity precursor-to-particle conversion rate, but the particle size is generally small (such as less than about 20 nm). There is a lack of a process that can generate large particles (defined as less than about 20 nm and as large as a micron) with high precursor utilization rate and with high throughput, such as a process that combines the advantages of the two general approaches outline above.

Discussed herein is a two-step process in which a non-thermal plasma is used first to fully consume a chemical precursor and convert it into very small particles (proto-particles), which are then carried through an intense heat source such as a tube furnace to grow their size. The particle growth mechanism in the second, thermal step can proceed with agglomeration and coagulation of the particles. Using this approach, particles larger than 20 nm can be reproducibly obtained with very high precursor utilization rate (thanks to the high reactivity of the first, non-thermal plasma step) and with low diffusional losses to the wall. This can occur because the nanoparticles that enter the second, thermal step have much lower diffusion coefficient (therefore probability of being lost to the wall) that an unreacted precursor still in molecular state,

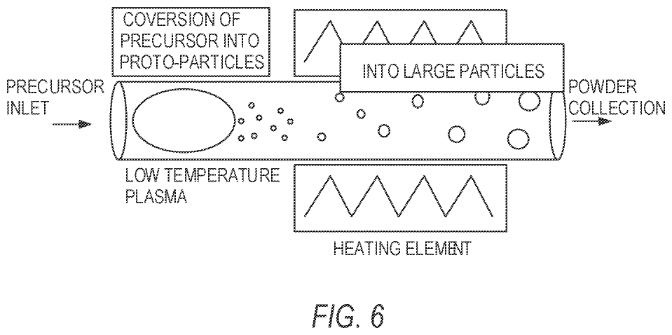

FIG. 6 depicts a schematic of a process for the synthesis of nanoparticles in the 1-1000 nm size range. A schematic showing a two-steps plasma-furnace process is shown in FIG. 6. The reactor can include a quartz tube in which an argon-silane mixture is flown. The silane mixture can be first exposed to a non-thermal plasma to rapidly consume the precursor and convert it into small particles. Typically, few milliseconds of reaction time are used to fully convert, for instance, silane into <10 nm amorphous clusters. After the first step, the aerosol (argon carrier gas+amorphous particles) can be passed through a tube furnace whose temperature set-point can be variable.

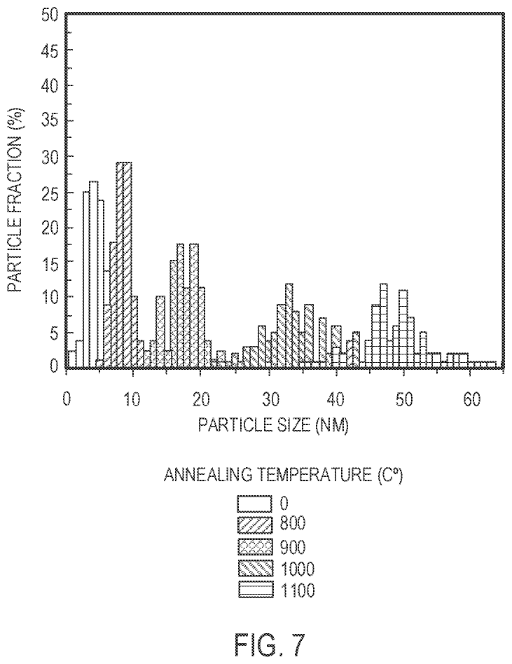

FIG. 7 depicts particle size distributions as a function of temperature in the second stage of the process. FIG. 7 shows the size distribution of the particles, as determined via TEM, as a function of furnace temperature. Using only the first step, the non-thermal plasma process, it is also possible to obtain nanoparticles with variable size and controllable structure (amorphous vs. crystalline), but the size control is limited to the “small particle” regime, such as less than about 20 nm.

This approach can produce larger particles with a tight control over particle size compared to a plasma-only approach. For the case of low-temperature plasmas, the growth process stops when the particles are around 10 nm in size. This is a consequence of electrostatic charging which effectively stops the agglomeration of the particles and prevents their coalescence into larger particles.

This approach also has advantages over conventional hot-wall reactor methods. Particles can be nucleated and grown in a hot-wall reactor. But such processes have the disadvantage of being relatively slow, and of being vulnerable to loss of precursor to the reactor walls. This occurs at the early stage of the nucleation process, when small radicals are rapidly lost to the reactor walls leading to the formation of a film. By comparison, the methods discussed herein allow for rapid nucleation in a plasma, so that diffusional losses are less prevalent when the particles enter the heating step. The diffusion of particles to the reactor wall can be much slower than that of small molecular species.

This approach has demonstrated reproducibility for the production of silicon particles in about the 50-100 nm size range. The reactor size that can be used is about 2″ in diameter. With a typical flow rate of about 850 sccm of 1.37% SiH4 in Argon, that leads to a production rate of roughly 1 gram/hour of silicon powder, with a >75% precursor-to-particle conversion rate.

FIG. 7 illustrates particle size distributions as a function of temperature in the second stage of the process. FIG. 7 shows the size distribution of the particles, as determined via TEM, as a function of furnace temperature. Using only the first step, (the non-thermal plasma process) it is also possible to obtain nanoparticles with variable size and controllable structure (amorphous vs. crystalline), but the size control is limited to the “small particle” regime, i.e. <20 nm. This is not ideal for some applications, such as for batteries, which require larger particles with smaller specific surface area.

This approach has the following two advantages. First, compared to a plasma-only approach, it can produce larger particles with a tight control over particle size. For the case of low-temperature plasmas, the growth process stops when the particles are around 10 nm in size. This is a consequence of electrostatic charging which effectively stops the agglomeration of the particles and prevents their coalescence into larger particles.

Second, particles can be nucleated and grown in a hot-wall reactor. But such process has the disadvantage of being relatively slow, and of being vulnerable to loss of precursor to the reactor walls. This occurs at the early stage of the nucleation process, when small radicals are rapidly lost to the reactor walls leading to the formation of a film. For the proposed process, nucleation occurs rapidly in a plasma, so that diffusional losses are less prevalent when the particles enter the heating step. While some diffusional losses are inevitable, the diffusion of particles to the reactor wall is much slower than that of small molecular species.

This approach has been prototyped in the lab. It has demonstrated great reproducibility for the production of silicon particles in the about 50-100 nm size range. The reactor size that is routinely used is about 2″ in diameter. With a typical flow rate of about 850 sccm of 1.37% SiHa in Argon, that led to a production rate of roughly 1 gram per hour of silicon powder, with a greater than about 75% precursor-to-particle conversion rate.

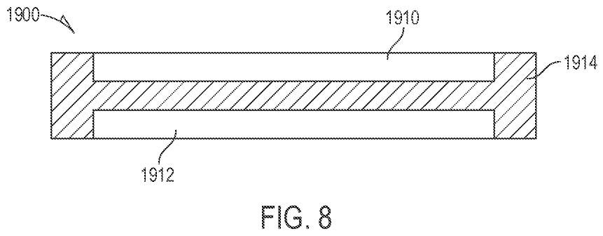

FIG. 8 shows an example of a battery 1900 according to an embodiment of the invention. The battery 1900 is shown including an anode 1910 and a cathode 1912. An electrolyte 1914 is shown between the anode 1910 and the cathode 1912. In one example, the battery 1900 is a lithium-ion battery. In one example, the anode 1910 includes sulfur as described in examples above. In one example, the cathode 1912 includes silicon as described in examples above. In one example, although the invention is not so limited, the battery 1900 is formed to comply with a 2032 coin type form factor.

To better illustrate the method and apparatuses disclosed herein, a non-limiting list of embodiments is provided here:

Example 1 can include silicon nanoparticles and a graphite carbon coating thereon.

Example 2 can include Example 1, wherein the silicon nanoparticles with the graphite coating comprise an average size of about 10 nm to about 100 nm.

Example 3 can include any of Examples 1-2, wherein the graphite carbon coating comprises a uniform carbon structure.

Example 4 can include any of Examples 1-3, wherein the graphite carbon coating comprises a substantially uniform thickness.

Example 5 can include any of Examples 1-4, wherein the graphite carbon coating comprises an ID/IG ratio on a Raman spectrum of about 1.2 to about 1.6.

Example 6 can include any of Examples 1-5, wherein the silicon nanoparticles have an average size of about 100 nm.

Example 7 can include any of Examples 1-6, wherein the anode material in a slurry of 1% in water comprises a charge/discharge capacity of about 2100 to about 2500 mAhg-1 over ten cycles.

Example 8 can include any of Examples 1-7, wherein the anode material in a slurry of 1% in water comprises a Coulombic efficiency of about 95% to about 100% over ten cycles.

Example 9. A method of making an anode material, including providing silicon nanoparticles; applying an amorphous carbon coating thereon to create an amorphous carbon shell on the silicon nanoparticles at a first temperature; and converting the amorphous carbon shell to a graphite carbon shell at a second temperature higher than the first temperature.

Example 10 can include Example 9, wherein applying the amorphous carbon comprises applying acetylene to the silicon nanoparticles.

Example 11 can include any of Examples 9-10, wherein the first temperature is about 650° C.

Example 12 can include any of Examples 9-11 wherein applying acetylene is done at a low pressure of about 3 Pa or less.

Example 13 can include any of Examples 9-12, wherein the second temperature is about 1000° C.

Example 14 can include any of Examples 9-13, wherein converting the amorphous shell to a graphite carbon shell comprises applying argon to the coating.

Example 15 can include any of Examples 9-14, wherein applying argon to the coating removes excess acetylene.

Example 16 can include an anode material made by the method of any of Examples 9-15.

Example 17 can include a method of producing silicon nanoparticles including providing an argon-silane mixture; exposing the argon-silane mixture to a non-thermal plasma to convert the silane mixture to amorphous clusters; and passing the amorphous clusters through a furnace at a first temperature so as to agglomerate them to silicon nanoparticles.

Example 18 can include Example 17, wherein the produced silicon nanoparticles have an average size of about 50 nm to about 100 nm.

Example 19 can include any of Examples 17-18, wherein passing the amorphous clusters through a furnace is done at a flow rate of about 850 sccm.

Example 20 can include any of Examples 17-19, wherein passing the amorphous clusters through a furnace is done at a temperature of about 900 C to about 1100 C.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in die art to best utilize the various example embodiments with various modifications as are suited to the particular use contemplated.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

The terminology used in the description of the example embodiments herein is for the purpose of describing particular example embodiments only and is not intended to be limiting. As used in the description of the example embodiments and the appended examples, the singular forms “a,” “an,” and “the” are intended to include the plural forms as well, unless the context clearly indicates otherwise, it will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending, on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context.

What is claimed is:

1. An anode material comprising:
silicon nanoparticles; and
a graphite carbon coating thereon.

2. The anode material of claim 1, wherein the silicon nanoparticles with the graphite coating comprise an average size of about 1 nm to about 200 nm.

3. The anode material of claim 1, wherein the graphite carbon coating comprises a uniform carbon structure.

4. The anode material of claim 1, wherein the graphite carbon coating comprises a substantially uniform thickness.

5. The anode material of claim 1, wherein the graphite carbon coating comprises an I_{D}/I_{G} ratio on a Raman spectrum of above about 1.

6. The anode material of claim 1, wherein the graphite carbon coating has a thickness of about 1 and 500 nm.

7. The anode material of claim 1, wherein the anode material comprises a charge/discharge capacity of about 2100 to about 2500 mAhg-1 over ten cycles.

8. The anode material of claim 1, wherein the anode material comprises a Coulombic efficiency of about 95% to about 100% over ten cycles.

9. A method of making an anode material, comprising:
providing silicon nanoparticles;
applying an amorphous carbon coating thereon to create an amorphous carbon shell on the silicon nanoparticles at a first temperature; and
converting the amorphous carbon shell to a graphite carbon shell at a second temperature higher than the first temperature.

10. The method of claim 9, wherein applying the amorphous carbon comprises applying acetylene to the silicon nanoparticles.

11. The method of claim 9, wherein the first temperature is about 400° C. to about 700° C.

12. The method of claim 10, wherein applying acetylene is done at a pressure of about 3 Pa or less.

13. The method of claim 9, wherein the second temperature is about 600° C. to about 1300° C.

14. The method of claim 10, wherein converting the amorphous shell to a graphite carbon shell comprises applying an inert gas to the coating.

15. The method of claim 14, wherein applying argon to the coating removes excess acetylene.

16. An anode material made by the method of claim 9.

17. A method of producing silicon nanoparticles comprising:
providing an argon-silane mixture;
exposing the argon-silane mixture to a non-thermal plasma to convert the silane mixture to amorphous clusters; and
passing the amorphous clusters through a furnace at a first temperature so as to agglomerate them to silicon nanoparticles.

18. The method of claim 17, wherein the produced silicon nanoparticles have an average size of about 50 nm to about 100 nm.

19. The method of claim 17, wherein passing the amorphous clusters through a furnace is done at a temperature of about 600 C to about 1500 C.
